(19) United States
(12) Patent Application Publication
(10) Pub. No.: US 2009/0008686 A1
(43) Pub. Date: Jan. 8, 2009

(54) SOLID-STATE IMAGING DEVICE WITH IMPROVED CHARGE TRANSFER EFFICIENCY

(76) Inventors: Motohiro MAEDA, Kawasaki-shi (JP); Hisanori Ihara, Yokkaichi-shi (JP); Hirofumi Yamashita, Kawasaki-shi (JP); Fumiaki Sano, Kamakura-shi (JP); Makoto Monoi, Tokyo (JP); Takanori Yagami, Fujisawa-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/166,621

(22) Filed: Jul. 2, 2008

(30) Foreign Application Priority Data
Jul. 6, 2007 (JP) 2007-178986

(51) Int. Cl. H01L 27/146

(52) U.S. Cl. 257/292; 257/E27.133

(57) ABSTRACT

A transfer gate is formed such that both end portions thereof in a second direction, which crosses a first direction in which a photodiode and a floating diffusion layer that is formed with a distance from the photodiode are arranged, are located inside boundaries with element isolation regions. Channel stopper layers are formed on surface portions of a device region in the vicinity of lower parts of both end portions of the transfer gate in the second direction in such a manner to extend to the boundaries with the element isolation regions.

### CROSS-REFERENCE TO RELATED APPLICATIONS

This application is based upon and claims the benefit of priority from prior Japanese Patent Application No. 2007-178986, filed Jul. 6, 2007, the entire contents of which are incorporated herein by reference.

### BACKGROUND OF THE INVENTION

1. Field of the Invention

The present invention relates generally to a solid-state imaging device which is used, for example, in a digital camera or a video camera, and more particularly to the structure of a transfer gate part which transfers signal charge, which is photoelectrically converted by a photodiode, to a floating diffusion layer.

2. Description of the Related Art

In these years, the pixel size of a solid-state imaging device, such as a CMOS sensor, has been decreased more and more in order to meet a demand for an increase in the number of pixels and a decrease in optical size. For example, in recent years, the pixel of the CMOS sensor which is used, for example, in a digital camera, is about 2 to 3 μm. If the pixel size decreases in this way, the following problems arise.

Since the distance between the pixel and the element isolation region decreases, the amount of variation of potential under the transfer gate, which is provided in the pixel, decreases. Consequently, signal charge cannot efficiently be transferred by the transfer gate. This leads to a problem of afterimage of a reproduced image. Specifically, there are many defects in the Si semiconductor substrate at boundary parts between the element isolation region, on the one hand, and the photodiode and the floating diffusion layer, on the other hand. If electrons flow into the photodiode and floating diffusion layer via the defects, dark current increases. In order to prevent this phenomenon, p-type diffusion layers are formed along the outer periphery of the element isolation region. The p-type diffusion layers are also formed in the channel region under the transfer gate. The presence of the p-type diffusion layer is a factor which affects the amount of variation of potential in the channel region under the transfer gate. Thus, in order to efficiently transfer the signal charge and to reduce afterimage, it is necessary to decrease the influence on the amount of variation of potential in the channel region.

In a photodiode in a conventional solid-state imaging device, a p-well region is formed in a p-type semiconductor substrate. Element isolation regions are formed on a surface of the p-well region. A floating diffusion layer is formed with a distance from the photodiode. A transfer gate is formed between the photodiode and the floating diffusion layer. P-type diffusion layers are formed along outer peripheries of the element isolation regions. The p-type diffusion layers function to reduce dark current which flows into the photodiode or the floating diffusion layer via many defects in the Si semiconductor layer, which are present at boundary parts between the element isolation regions, on the one hand, and the photodiode and the floating diffusion layer, on the other hand. The element isolation regions and the p-type diffusion layers are connected to a ground potential.

Next, the operation of the solid-state imaging device with this structure is described. In a signal storage period, the transfer gate is turned off, and charge is accumulated in the photodiode. In a signal read period, the transfer gate is turned on, and the signal charge that is accumulated in the photodiode is read out to the floating diffusion layer via the channel region under the transfer gate.

In a case where the width of the transfer gate (channel width) is sufficiently large, even if p-type diffusion layers are present in the channel region, a substantial transfer channel width, which excludes the formation region of the p-type diffusion layers, can sufficiently be secured. Thus, the channel region is hardly affected by the ground potential. When a read potential is applied to the transfer gate, the potential of the channel region becomes sufficiently higher than the potential of the photodiode, and the signal charge can efficiently be transferred to the floating diffusion layer.

When the pixel is made finer in size, the following problem occurs in the signal read operation. If the channel width decreases in accordance with the reduction in size of the pixel, the substantial transfer channel width, excluding the formation region of the p-type diffusion layers, also decreases. In this case, even if a sufficiently high voltage is applied to the transfer gate, the potential of the channel region is greatly affected by the fixed ground potential of the p-type diffusion layers which are formed along the element isolation regions. Consequently, the potential of the channel region cannot be increased enough to efficiently transfer the signal charge that is stored in the photodiode. Hence, even after the read operation by the transfer gate, charge remains in the photodiode and afterimage occurs, leading to degradation in S/N ratio of a reproduced screen. Under the circumstances, there is a demand for a solid-state imaging device which can efficiently perform charge transfer from the photodiode to the floating diffusion layer, even if the pixel size is reduced.

Jpn. Pat. Appln. KOKAI Publication No. 2005-101442 discloses a solid-state imaging device which can efficiently perform charge transfer from the photodiode to the floating diffusion layer by providing a transfer gate, which has a projection-and-recess portion toward the floating diffusion layer side, on the substrate between the photodiode and the floating diffusion layer.

### BRIEF SUMMARY OF THE INVENTION

According to a first aspect of the present invention, there is provided a solid-state imaging device comprising: a device region formed on a semiconductor substrate and being isolated by an element isolation region; a photodiode formed on a surface of the device region; a floating diffusion layer formed on a surface of the device region and being spaced apart from the photodiode; a transfer gate formed on the device region between the photodiode and the floating diffusion layer, at least one end portion of the transfer gate in a second direction, which crosses a first direction in which the photodiode and the floating diffusion layer are arranged, being spaced apart from the element isolation region; and a channel stopper layer formed in a surface portion of the device region between a lower part of the at least one end portion of the transfer gate in the second direction and the element isolation region.

According to a second aspect of the present invention, there is provided a solid-state imaging device comprising: an imaging region formed on a semiconductor substrate, the imaging region including a plurality of unit pixels arranged in a two-dimensional fashion, each of the plurality of unit pixels including a photoelectric conversion unit and a signal scan circuit unit, each of the unit pixels including: a device region isolated by an element isolation region; a photodiode formed in the device region and constituting the photoelectric conversion unit; a floating diffusion layer spaced apart from the photodiode; a transfer gate formed between the photodiode and the floating diffusion layer, at least one end portion of the transfer gate in a second direction, which crosses a first direction in which the photodiode and the floating diffusion layer are arranged, being spaced apart from the element isolation region; and a channel stopper layer formed in a surface portion of the device region between a lower part of the at least one end portion of the transfer gate in the second direction and the element isolation region.

### BRIEF DESCRIPTION OF THE SEVERAL VIEWS OF THE DRAWING

FIG. 1 is a circuit diagram showing the structure of the entirety of a pixel array in a solid-state imaging device according to an embodiment of the present invention;

FIG. 2 is a pattern plan view showing a region of one photodiode, which is extracted from the solid-state imaging device shown in FIG. 1;

FIG. 3 is a cross-sectional view showing a device structure, taken along line A-A in FIG. 2;

FIG. 4 is a potential diagram showing a potential state, taken along line B-B in FIG. 2;

FIG. 5 is a pattern plan view showing an example of disposition of a plurality of unit cells in FIG. 1; and

FIG. 6 is a waveform diagram showing an example of the operation of a transfer gate.

### DETAILED DESCRIPTION OF THE INVENTION

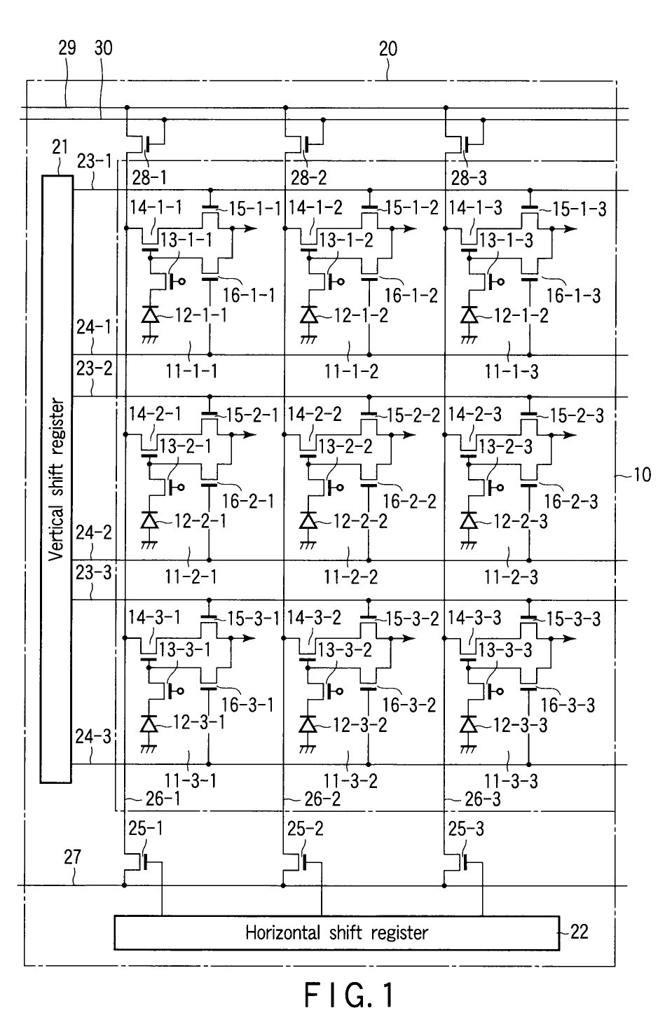

FIG. 1 is a circuit diagram showing the structure of the entirety of a pixel array in a solid-state imaging device according to an embodiment of the present invention. In FIG. 1, reference numeral 10 denotes a pixel region that is an imaging region, and numeral 20 denotes a peripheral circuit region. In the pixel region 10, a plurality of unit pixels (unit cells) 11 are arrayed in a two-dimensional fashion.

For the purpose of simple depiction, FIG. 1 shows, for example, unit cells 11-1-1 to 11-3-3 of three rows X three columns. Further, in the pixel region 10, there are provided horizontal address lines 23-1 to 23-3, reset lines 24-1 to 24-3 and vertical signal lines 26-1 to 26-3.

In the peripheral circuit region 20, there are provided a vertical shift register 21 which scans the pixel region 10, a horizontal shift register 22, vertical signal lines 26-1 to 26-3, load transistors 28-1 to 28-3, horizontal select transistors 25-1 to 25-3, and a horizontal signal line 27.

Each of the unit cells 11-1-1 to 11-3-3 is composed of, for example, a photodiode, 12-1-1 to 12-3-3; a transfer gate 13-1-1 to 13-3-3, which reads out an output signal (photoelectric conversion signal) of the photodiode; an amplifying transistor, 14-1-1 to 14-3-3, which amplifies an output signal of the transfer gate; a vertical select transistor, 15-1-1 to 15-3-3, which selects a vertical line for reading out an output signal of the amplifying transistor; and a reset transistor, 16-1-1 to 16-3-3, which resets an output signal charge of the photodiode.

One end of each horizontal address line, 23-1 to 23-3, is connected to the vertical shift register 21 on the peripheral circuit region 20, and is horizontally disposed. The horizontal address lines 23-1 to 23-3 are connected to the gates of the vertical select transistors 15-1-1 to 15-1-3, 15-2-1 to 15-2-3 and 15-3-1 to 15-3-3, and designate lines for reading out signals.

One end of each reset line, 24-1 to 24-3, is connected to the vertical shift register 21 and is horizontally disposed. The reset lines 24-1 to 24-3 are connected to the gates of the reset transistors.

The vertical signal lines 26-1 to 26-3 are connected to the sources of the amplifying transistors 14-1-1 to 14-1-3, 14-2-1 to 14-2-3 and 14-3-1 to 14-3-3. One end of the vertical signal line, 26-1 to 26-3, is connected to one end of the load transistor, 28-1 to 28-3, provided on the peripheral circuit region 20. The other end of the load transistor, 28-1 to 28-3, is connected to a wiring line 29, the gate thereof is connected to a wiring line 30. The other end of the vertical signal line, 26-1 to 26-3, is connected to the horizontal signal line 27 via the horizontal select transistor, 25-1 to 25-3, provided on the peripheral circuit region 20. The gates of the horizontal select transistor 25-1 to 25-3 are connected to the horizontal shift register 22, and are selected by select pulses which are supplied from the horizontal shift register 22.

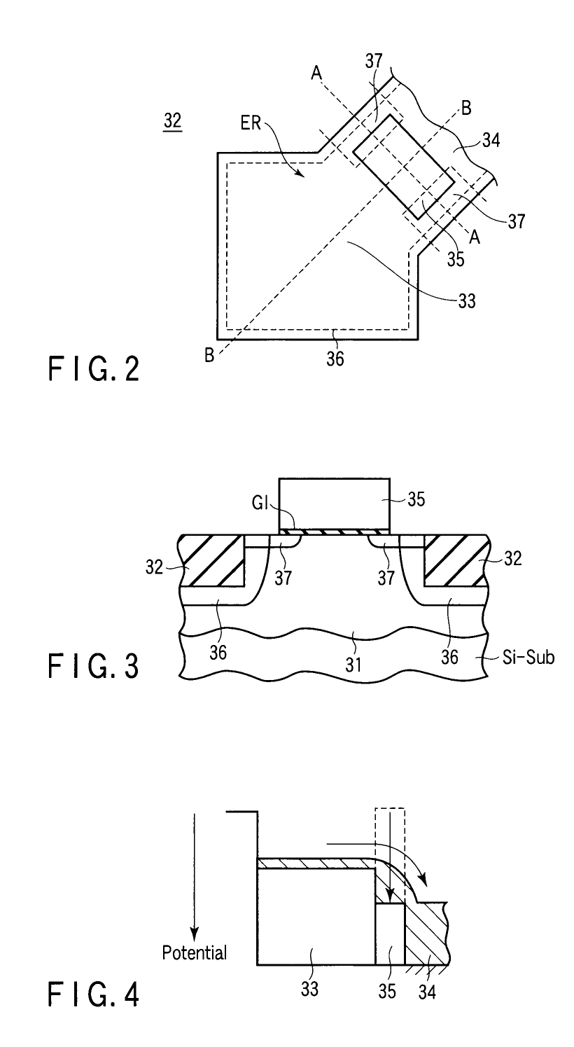

FIG. 2 is a pattern plan view showing a region of one photodiode, which is extracted from the solid-state imaging device shown in FIG. 1. FIG. 3 is a cross-sectional view showing a device structure, taken along line A-A in FIG. 2. FIG. 4 is a potential diagram showing a potential state, taken along line B-B in FIG. 2.

In FIG. 2 and FIG. 3, reference numeral 31 denotes a p-well region which is formed on a Si semiconductor substrate (Si-sub), and numeral 32 denotes an element isolation region (STI) which is formed on a surface of the p-well region 31. Reference numeral 33 denotes a photodiode which is formed of an n-type diffusion layer, and numeral 34 denotes a floating diffusion layer which is formed of an n-type diffusion layer and spaced apart from the photodiode 33. Reference numeral 35 denotes a transfer gate, and numeral 36 denotes a p-type diffusion layer which is formed in the p-well region 31 along an outer periphery of the element isolation region 32. The element isolation region 32 is formed around a device region ER, and the p-type diffusion layer 36 functions as a dark current preventing layer which suppresses generation of dark current due to a defect that is present in the Si semiconductor layer. The photodiode 33 and floating diffusion layer 34 are formed on the surface of the device region RE which is isolated by the element isolation region 32. The element isolation region 32 and the p-type diffusion layer 36, which is formed on the outer periphery of the element isolation region 32, are both connected to a ground potential.

The transfer gate 35 is formed via a gate insulation film GI on the device region ER between the photodiode 33 and the floating diffusion layer 34. The length between both ends of the transfer gate 35 in the channel width direction is less than the distance between the element isolation regions 32 and is less than the distance between the p-type diffusion layers 36. In other words, both end portions of the transfer gate 35 in a second direction (a direction along line A-A) crossing a first direction (a direction along line B-B) in which the photodiode 33 and floating diffusion layer 34 are arranged, that is, both end portions of the transfer gate 35 in the right-and-left direction (channel width direction) in FIG. 3, are located inside the opposed element isolation regions 32. In addition, the transfer gate 35 is spaced apart from the p-type diffusion layers 36 which are formed along the outer peripheries of the element isolation regions 32.

Channel stopper layers 37, which are formed of p-type diffusion layers, are formed in device regions between lower parts of the transfer gate 35 at both ends in the channel width direction, on the one hand, and the element isolation regions 32, on the other hand.

The p-type diffusion layer 36 and channel stopper layer 37 include, for instance, B (boron) as p-type impurities. The p-type diffusion layer 36 has an impurity concentration of about 1×10¹⁷˜10¹⁸ (cm⁻³). The channel stopper layer 37 has an impurity concentration of about 1×10¹⁶˜10¹⁷ (cm⁻³). The impurity concentration of the channel stopper layer 37 is lower than the impurity concentration of the p-type diffusion layer 36.

FIG. 4 shows a state in which signal charge is transferred from the photodiode 33 to the floating diffusion layer 34 via the transfer gate 35.

According to the above-described embodiment, as shown in FIG. 3, the transfer gate 35 is spaced apart from the element isolation regions 32 and from the p-type diffusion layers 36 which are formed along the outer peripheries of the element isolation regions 32. If the transfer gate 35 is structured in this fashion, the channel region under the transfer gate is not affected by the potential of the element isolation regions 32 and the p-type diffusion layers 36. Thus, as shown in FIG. 4, the channel potential at a time when a read potential is applied to the transfer gate 35 can sufficiently be set at a high value. Thereby, the signal charge that is stored in the photodiode 33 can efficiently be transferred to the floating diffusion layer 34 via the transfer gate 35. In this case, the potential under the transfer gate can be controlled by applying a negative voltage to the transfer gate 35 at least during a predetermined time of a signal storage period.

The channel stopper layers 37 are formed at lower parts of the transfer gate 35. Thus, even if the transfer gate 35 is spaced apart from the element isolation regions 32 and p-type diffusion layers 36, the signal charge that is stored in the photodiode 33 does not leak to the floating diffusion layer 34 while the transfer gate 35 is in the OFF state.

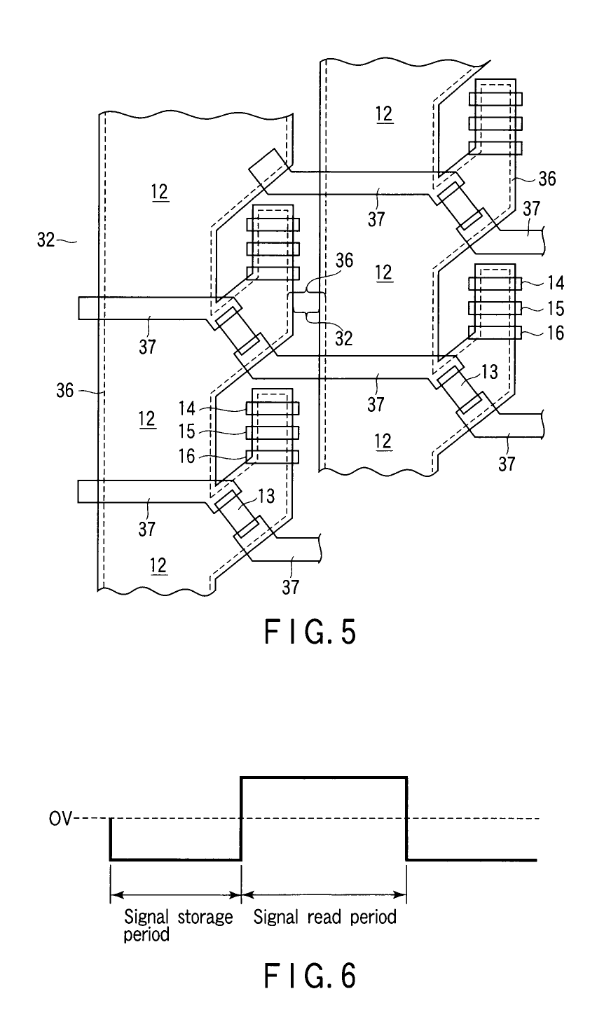

FIG. 5 is a pattern plan view showing an example of disposition of a plurality of unit cells in FIG. 1. The parts common to those in FIG. 1 to FIG. 3 are denoted by like reference numerals, and a description thereof is omitted.

As shown in FIG. 5, each channel stopper layer 37 is formed in a manner to extend up to a position between photodiodes 12 (33) which neighbor in the horizontal direction, and a plurality of photodiodes 12 are mutually separated by the channel stopper layers 37. Actually, the channel stopper layer 37 is separated at a part where the element isolation region 32 is present. By isolating the photodiodes by the channel stopper layers 37 in this manner, the photodiodes, which cannot be isolated by the element isolation regions (STI), can be isolated.

The present invention is not limited to the above-described embodiment, and various modifications may be made. For example, the transfer gate 35 is formed to be separated from the element isolation regions 32 and the p-type diffusion layers 36 that are formed along the outer peripheries of the element isolation regions 32. As a result, when the transfer gate 35 is in the OFF state, there is a tendency that the potential under the transfer gate becomes slightly higher than in the case of the conventional structure, and there are cases where signal charge leak may occur, or a depletion layer may spread over a Si semiconductor layer surface under the transfer gate, leading to occurrence of dark current. However, as shown in FIG. 6, the channel potential under the transfer gate can be kept low by applying a negative voltage to the transfer gate at least during a predetermined time in the signal storage period. Thus, when the transfer gate is in the ON state, the channel potential can be made high enough to read out the signal charge stored in the photodiode 33. Therefore, the amplitude of the channel potential of the transfer gate 35 can be increased, and the signal charge that is stored in the photodiode 33 can be increased. FIG. 6 shows merely an example, and the time period in which the negative potential is applied is not limited to the example in FIG. 6.

Furthermore, when the transfer gate 35 is in the OFF state, a negative voltage is applied to the transfer gate at least during a predetermined time in the signal storage period. Thereby, holes accumulate in the Si semiconductor layer surface portion under the transfer gate, and dark current noise, which occurs at the interface of the channel region under the transfer gate, can be reduced. Therefore, a sufficient S/N ratio can be realized on a reproduction screen, without degrading the device reliability.

In FIG. 2 and FIG. 3, the conductivity type of the p-type semiconductor substrate and the conductivity type of the p-well region 31, which is formed on the p-type semiconductor substrate, are set to be the p type. However, the invention is not limited to this example and, alternatively, an n-well region may be formed on an n-type semiconductor substrate.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A solid-state imaging device comprising:
a device region formed on a semiconductor substrate and being isolated by an element isolation region;
a photodiode formed on a surface of the device region;
a floating diffusion layer formed on a surface of the device region and being spaced apart from the photodiode;
a transfer gate formed on the device region between the photodiode and the floating diffusion layer, at least one end portion of the transfer gate in a second direction, which crosses a first direction in which the photodiode and the floating diffusion layer are arranged, being spaced apart from the element isolation region; and
a channel stopper layer formed in a surface portion of the device region between a lower part of the at least one end portion of the transfer gate in the second direction and the element isolation region.

2. The device according to claim 1, wherein a length of the transfer gate in the second direction is less than a distance between the element isolation regions which are opposed in the second direction.

3. The device according to claim 1, further comprising a first diffusion layer formed at an outer periphery of the element isolation region and functioned as a dark current preventing layer.

4. The device according to claim 3, wherein at least one end portion of the transfer gate is spaced apart from the first diffusion layer.

5. The device according to claim 4, wherein the channel stopper layer extends from the element isolation region to a lower part of the transfer gate.

6. The device according to claim 5, wherein the channel stopper layer is a second diffusion layer.

7. The device according to claim 6, wherein the channel stopper layer and the first diffusion layer include impurities of the same conductivity type, and an impurity concentration of the channel stopper layer is lower than an impurity concentration of the first diffusion layer.

8. The device according to claim 1, wherein a negative potential is applied to the transfer gate at least during a part of a signal storage period.

9. A solid-state imaging system in which the solid-state imaging devices according to claim 1 are arranged in a matrix.

10. A solid-state imaging device comprising:
an imaging region formed on a semiconductor substrate, the imaging region including a plurality of unit pixels arranged in a two-dimensional fashion, each of the plurality of unit pixels including a photoelectric conversion unit and a signal scan circuit unit,
each of the unit pixels including:
a device region isolated by an element isolation region;
a photodiode formed in the device region and constituting the photoelectric conversion unit;
a floating diffusion layer spaced apart from the photodiode;
a transfer gate formed between the photodiode and the floating diffusion layer, at least one end portion of the transfer gate in a second direction, which crosses a first direction in which the photodiode and the floating diffusion layer are arranged, being spaced apart from the element isolation region; and
a channel stopper layer formed in a surface portion of the device region between a lower part of the at least one end portion of the transfer gate in the second direction and the element isolation region.

11. The device according to claim 10, wherein the channel stopper layer is also formed between the photodiodes of the plurality of unit pixels, and the photodiodes of the plurality of unit pixels are mutually isolated by the channel stopper layer.

12. The device according to claim 10, wherein a length of the transfer gate in the second direction is less than a distance between the element isolation regions which are opposed in the second direction.

13. The device according to claim 10, further comprising a first diffusion layer formed at an outer periphery of the element isolation region and functioned as a dark current preventing layer.

14. The device according to claim 13, wherein at least one end portion of the transfer gate is spaced apart from the first diffusion layer.

15. The device according to claim 14, wherein the channel stopper layer extends from the element isolation region to a lower part of the transfer gate.

16. The device according to claim 15, wherein the channel stopper layer is a second diffusion layer.

17. The device according to claim 16, wherein the channel stopper layer and the first diffusion layer include impurities of the same conductivity type, and an impurity concentration of the channel stopper layer is lower than an impurity concentration of the first diffusion layer.

18. The device according to claim 10, wherein a negative potential is applied to the transfer gate at least during a part of a signal storage period.
